(19) United States
(12) Patent Application Publication
(10) Pub. No.: US 2007/0019370 A1
(43) Pub. Date: Jan. 25, 2007

(54) Portable computer

(76) Inventor: Hwan-myung Noh, Suwon-si (KR)

Correspondence Address: STANZIONE & KIM, LLP, 919 18TH STREET, N.W., SUITE 440, WASHINGTON, DC, 20006, US

(21) Appl. No.: 11/357,143

(22) Filed: Feb. 21, 2006

(30) Foreign Application Priority Data
Jul. 7, 2005 (KR) 2005-61394

(51) Int. Cl. H05K 5/00

(52) U.S. Cl. 361/679

(57) ABSTRACT

A portable computer includes a main body, a monitor to form an image thereon, a combining member rotatably coupled with the monitor, and a locking unit having an engaging part provided at one of the combining member and the main body and a hanging part provided at the other one of the combining member and the main body, the hanging part being capable of attaching and detaching the monitor to the main body by rotating between a coupling position at which the hanging part is coupled with the engaging part and a separating position at which the hanging part is separated from with the engaging part. Accordingly, the monitor can easily be attached to and detached from the main body of the portable computer.

### CROSS-REFERENCE TO RELATED APPLICATIONS

This application claims priority under 35 U.S.C. § 119 from Korean Patent Application No. 2005-61394, filed on Jul. 7, 2005, in the Korean Intellectual Property Office, the disclosure of which is incorporated herein in its entirety by reference.

### BACKGROUND OF THE INVENTION

1. Field of the Invention

The present general inventive concept relates to a portable computer, and more particularly, to a portable computer which has an improved structure to couple a main body with a display unit.

2. Description of the Related Art

In general, a portable computer comprises a main body, a display unit receiving an image signal transmitted from the main body and forming an image, and a tilting hinge combining the display unit with the main body for enabling the display unit to tilt with respect to the main body.

A conventional portable computer having a display unit mounted detachably thereto is disclosed in Korean Patent Application No. 10-1997-40363. Such a conventional portable computer comprises a laptop type main body, a liquid crystal display (LCD) module forming an image, a LCD module mounting unit which is detachably coupled with the LCD module and a hinge part coupling the main body with the LCD module mounting unit for enabling the LCD module mounting unit to pivot with respect to the main body.

A first connecting terminal and a combining pin are provided at one side of the LCD module. A second connecting terminal to be connected to the first connecting terminal and a accommodating groove part to be combined with the combining pin are formed on the LCD module mounting unit.

The accommodating groove part has a plurality of accommodating grooves for accommodating the different sized combining pins provided at the various sized LCD modules.

Accordingly, in such a conventional portable computer in which the display unit can be detached from the main body, various sized LCD modules can be selectively mounted to the main body.

However, although such a conventional portable computer has a structure for separating the display unit from the main body, there is no structure for detaching the display unit from the main body and enabling the separated display unit to be used as a separate monitor.

Furthermore, in the conventional portable computer, it is desirable that the user be able to detach and couple the display unit and the main body more easily, and it is desirable to improve the combining structure so as to prevent an inconvenience such as vibrations generated at the time of combining the display unit and the main body.

### SUMMARY OF THE INVENTION

Accordingly, the present general inventive concept provides a portable computer in which a monitor can be easily attached to and detached from a main body.

The present general inventive concept also provides a portable computer in which a monitor can be detached from the main body and the detached monitor can be used as a separate monitor.

Additional aspects and utilities of the present general inventive concept will be set forth in part in the description which follows and, in part, will be obvious from the description, or may be learned by practice of the present general inventive concept.

The foregoing and/or other aspects of the present general inventive concept are achieved by providing a portable computer, comprising a main body, a monitor to form an image thereon, a combining member rotatably coupled with the monitor, and a locking unit having an engaging part provided at one of the combining member and the main body and a hanging part provided at the other one of the combining member and the main body, the hanging part being capable of attaching and detaching the monitor and the main body by rotating between a coupling position at which the hanging part is coupled with the engaging part and a separating position at which the hanging part is separated from with the engaging part.

The locking unit may comprise a rotational shaft to rotatably support the hanging part.

The hanging part may comprise a circular arc-shaped part protruding at a predetermined angle from the rotational shaft in a radial direction of the rotational shaft and a hanging protrusion provided at the circular arc-shaped part to hang on the engaging part when the hanging part is in the coupling position.

The engaging part may comprise a circular arc shaped accommodating part to accommodate the circular arc-shaped part and a hanging protrusion accommodating part to accommodate the hanging protrusion to support the hanging protrusion in a hanging state when the hanging part is in the coupling position.

The engaging part may be provided at the combining member, and the hanging part may be rotatably provided at the main body.

The locking unit may further comprise a rotational shaft supporting part provided at the main body to rotatably support the rotational shaft.

The combining member may comprise a pair of combining supporters spaced a predetermined distance from each other, and the engaging part may comprise first and second engaging parts respectively provided at the pair of combining supporters.

At least one of the combining supporters may comprise a connector, and the main body may be provided with a connecting port to be connectable to the connector.

The portable computer may further comprise an elastic member provided between the connecting port and the main body to elastically couple the connecting port with the main body.

The portable computer may further comprise a connecting cable to connect the connector and the connecting port when the monitor is detached from the main body.

The rotational shaft may comprise a tool accommodating part formed at one end thereof to accommodate a rotational tool to rotate the rotational shaft.

The foregoing and/or other aspects of the present general inventive concept are also achieved by providing a portable computer, comprising a display unit comprising one or more accommodating portions, each accommodating portion having one or more arc shaped grooves, and a main body comprising one or more rotatable shafts corresponding to the one or more accommodating portions, each rotatable shaft having one or more arc shaped protruding portions protruding therefrom to be accommodated within the one or more arc shaped grooves of the corresponding accommodating portion to attach the display unit to the main body when the respective rotatable shaft rotates to a first position, and to separate from the one or more arc shaped grooves of the corresponding accommodating portion to detach the display unit from the main body when the respective rotatable shaft rotates to a second position.

The foregoing and/or other aspects of the present general inventive concept are also achieved by providing a portable computer, comprising a main body comprising a rotatable hanging unit and a connecting port, a display unit comprising an engaging unit to couple with the rotatable hanging unit to attach the display unit to the main body and to separate from the rotatable hanging unit to detach the display unit from the main body according to a rotation of the rotatable hanging unit, and a connector to automatically connect with the connecting port when the display unit is attached to the main body and connectable to the connecting port of the main body and one or more external devices when the display unit is detached from the main body.

The foregoing and/or other aspects of the present general inventive concept are also achieved by providing a display device attachable to a main body of a portable computer, comprising a display unit to display an image thereon, and a coupling unit coupled to the display unit and including an engaging part to engage and disengage with a rotatable portion of the main body of the portable computer according to a rotation of the rotatable portion, and a connector connectable to the main body of the portable computer and to one or more external devices to input the image to be displayed on the display unit.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a perspective view illustrating a portable computer according to an embodiment of the present general inventive concept;

FIGS. 2 and 3 are exploded perspective views illustrating the portable computer of FIG. 1;

FIGS. 4 and 5 are exploded perspective bottom views illustrating the portable computer of FIG. 1, as seen from a rear side thereof;

FIGS. 6-8 are partial perspective bottom views illustrating a state in which a monitor is coupled to a main body by a locking unit of the portable computer of FIG. 1; and

FIG. 9 is a perspective view illustrating a state in which the monitor is separated from the main body of the portable computer of FIG. 1.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

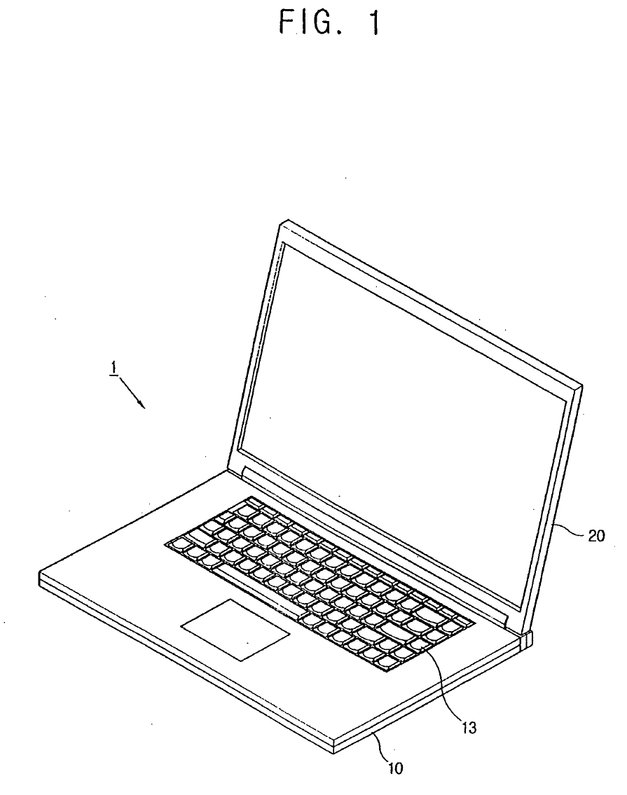

FIGS. 1-5 illustrate a portable computer 1 according to an embodiment of the present general inventive concept. Referring to FIGS. 1-5, the portable computer 1 comprises a main body 10, a monitor 20 to form an image thereon, a combining member 40 rotatably coupled with the monitor 20, and a locking unit 50 provided at the combining member 40 and the main body 10 to attachably and detachably couple the combining member 40 with the main body 10.

The main body 10 can stably rest on a horizontal surface, such as a table. The main body 10 may comprise components such as a main board and a central processing unit (CPU) and the like mounted therein to generate an image signal and the like, and a keyboard 13 provided to input data.

The monitor 20 receives the image signal and forms and displays the image corresponding to the received image signal. A driving circuit (not shown) can be provided in the monitor 20 to drive the monitor 20 to receive the image signal and form the image. An LCD panel with a thin thickness and a light weight can be used as the monitor 20 to form the image. However, a flat display panel, such as a plasma display panel (PDP), can also be used as the monitor 20. The monitor 20 is coupled with a shaft supporting part 33 of a hinge part 30 described below, which allows the monitor 20 to be rotatable with respect to the combining member 40.

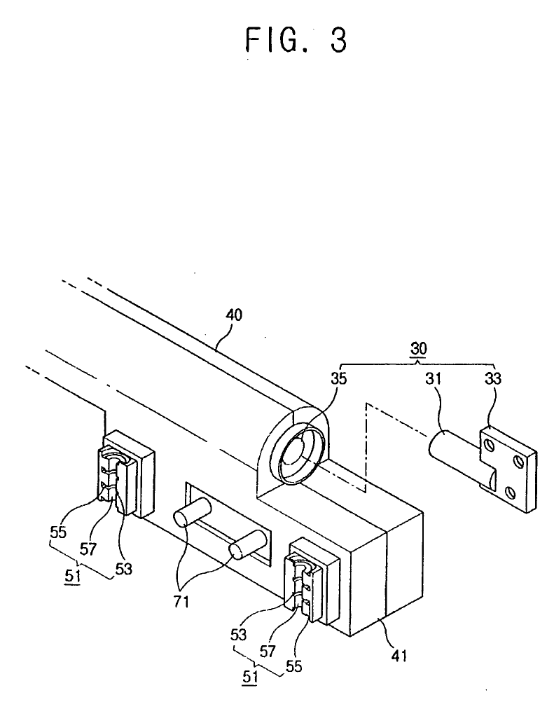

The hinge part 30 supports the monitor 20 and the combining member 40 such that the monitor 20 can be tilted on a horizontal shaft line with respect to the combining member 40. As illustrated in FIG. 3, the hinge part 30 may comprise a hinge shaft 31 provided between the monitor 20 and the combining member 40, the shaft supporting part 33 provided at a first side of the hinge shaft 31 and coupled with the monitor 20, and a shaft accommodating part 35 provided at the combining member 40 to accommodate the second side of the hinge shaft 31.

A pair of the hinge shafts 31 can be provided, each of which having a horizontal shaft line. One of the hinge shafts 31 can be connected to a first side of a lower end of the monitor 20 and a first side of an upper end of the combining member 40, the other one of the hinge shafts 31 can be connected to a second side of the lower end of the monitor 20 and a second side of the upper end of the combining member 40. The shaft supporting part 33 extends from the first side of the hinge shaft 31 and can be coupled with the monitor 20 through a screw or the like. Accordingly, the shaft supporting part 33 can rotate integrally with the monitor 20.

The second side of the hinge shaft 31 is rotatably coupled with the shaft accommodating part 35 of the combining member 40 and a predetermined frictional force is generated between the hinge shaft 31 and the shaft accommodating part 35. Thus, if a user wants to tilt the monitor 20 with respect to the main body 10, the user can apply a force to the monitor 20 greater than the frictional force between the hinge shaft 31 and the shaft accommodating part 35.

The combining member 40 can be disposed at a rear surface of the main body 10 and coupled with the main body 10 by the locking unit 50. The combining member 40 may comprise a pair of combining supporters 41 formed at and protruding from the first and second sides thereof. The shaft accommodating parts 35 are also provided at the first and second ends of the combining member 40 as described above. In a case in which the combining member 40 is detached from the main body 10 and mounted to a separate stand (not shown), the hinge part 30 is still provided between the monitor 20 and the combining member 40 so that the monitor 20 can be tilted with respect to the stand (not shown) by the hinge part 30.

An engaging part 51 of the locking unit 50 can be provided at each combining supporter 41, and each combining supporter 41 can be coupled with the rear surface of the main body 10 through the locking unit 50. Accordingly, it is possible to assemble the portable computer 1 with a thin thickness by coupling the combining supporters 41 with the rear surface of the main body 10. Each combining supporter 41 can be provided with a connector 71 which can be connected with a connecting port 73 provided on the main body 10.

The locking unit 50 comprises the engaging part 51 provided at one of the combining member 40 and the main body 10 and a hanging part 61 provided at the other one of the combining member 40 and the main body 10. The hanging part 61 can be rotated between a coupling position at which the hanging part 61 is coupled with the engaging part 51 and a separating position at which the hanging part 61 is separated from the engaging part 51. The locking unit 50 can further comprise a rotational shaft 67 to rotatably support the hanging part 61.

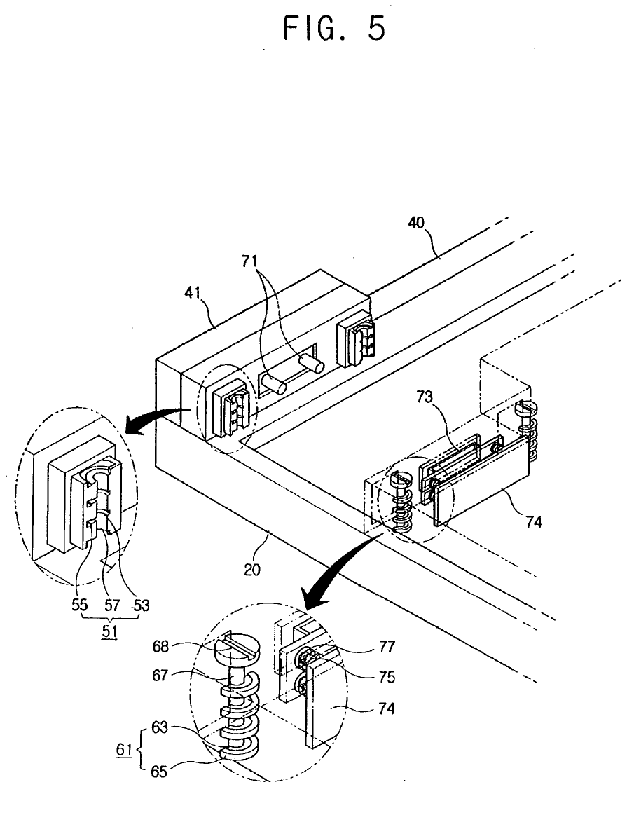

As illustrated in FIG. 5, the hanging part 61 may comprise a circular arc-shaped part 63 protruding at a predetermined angle from the rotational shaft 67 in a radial direction of the rotational shaft 67 and a hanging protrusion 65 provided at the circular arc-shaped part 63 to hang on the engaging part 51 when the hanging part 61 is in the coupling position.

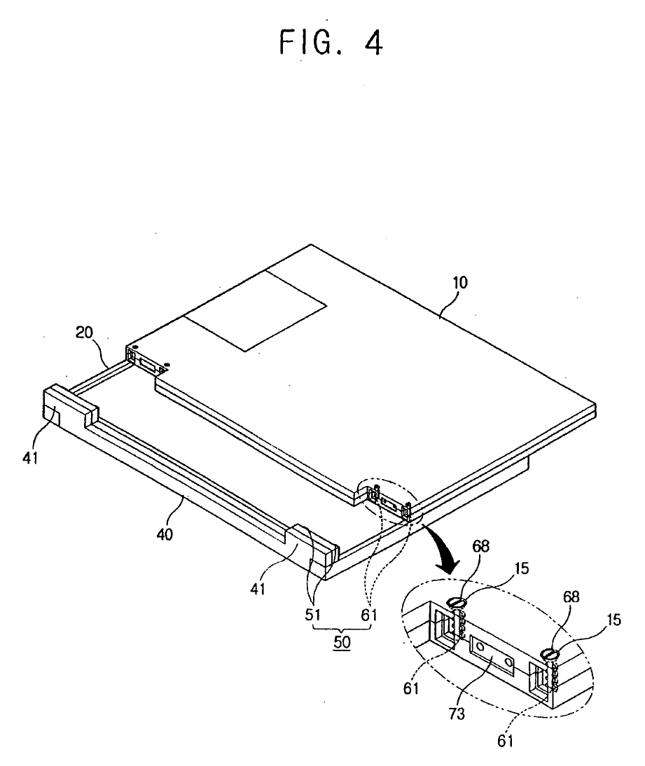

The rotational shaft 67 can have a long rod shape, as illustrated in FIG. 5, and is rotatably provided at a rotational shaft supporting part 15 formed at the rear surface of the main body 10. A tool accommodating part 68 can be formed at one end of the rotational shaft 67, and a rotational tool (not shown) can be accommodated by the tool accommodating part 68 and used to rotate the rotational shaft 67. As illustrated in FIGS. 4 and 5, the rotational shaft 67 is supported by the rotational shaft supporting part 15 formed at the rear surface of the main body 10. However, if the engaging part 51 is provided at the main body 10, the rotational shaft 67 can be provided at the combining supporter 41. As illustrated in FIGS. 4 and 5, a pair of the rotational shafts 67 are provided, and one of the rotational shafts 67 is disposed at each of opposite sides of the rear surface of the main body 10 to correspond to each engaging part 51 disposed at the first and second sides of the combining member 40. However, the number of the rotational shaft 67 is not limited. For example, two rotational shafts 67 can be provided at each of the opposite sides of the rear surface of the main body 10.

The tool accommodating part 68 can be a slit formed at the end of the rotational shaft 67 to accommodate the rotational tool, such as a coin or a screwdriver, such that the rotational shaft 67 can be rotated by the rotational tool. Therefore, the user can insert the rotational tool (not shown) into the tool combining part 68 and easily rotate the rotational shaft 67. Although the tool accommodating part 68 is illustrated in FIGS. 4 and 5, the present general inventive concept is not limited thereto, and the rotational shaft 67 may be formed to be rotatable without a rotating tool.

The circular arc-shaped parts 63 protrude from an outer circumference surface of the rotational shaft 67 in the radial direction of the rotational shaft 67. As illustrated in the embodiment of FIG. 5, each circular arc-shaped part 63 protrude at 180° to form a semicircular shape. However, each circular arc-shaped part 63 can protrude at any angle in the radial direction of the rotational shaft 67 in which the circular arc-shaped part 63 can be supported by and separated from the engaging part 51. For example, it is possible that the angle is approximately between 90° to 180°. In the embodiment of the present general inventive concept as illustrated in FIG. 5, four of the circular arc-shaped parts 63 are formed on each rotational shaft 67 at predetermined intervals. However, the number of the circular arc-shaped parts 63 provided on each rotational shaft 67 is not limited thereto, and can be less than 3 or greater than 5, as well.

As illustrated in FIG. 5, the hanging protrusion 65 is formed at an outer end portion of each circular arc-shaped part 63 and has a thickness which is thicker than that of the circular arc-shaped part 63. Each hanging protrusion 65 is accommodated by a corresponding hanging protrusion accommodating part 55 of the engaging part 51 when the hanging part 61 is in the coupling position and rotates with the rotational shaft 67. Accordingly, when the hanging part 61 is in the coupling position, each hanging protrusion 65 is accommodated in the corresponding hanging protrusion accommodating part 55 of the engaging part 51 to prevent the combining supporter 41 from being separated from the main body 10.

As illustrated in FIG. 5, the engaging part 51 is provided at the combining supporter 41. However, the engaging part 51 may alternatively be provided at the main body 10. The engaging part 51 comprises circular arc shaped accommodating parts 53 to accommodate the circular arc-shaped parts 63 of the hanging part 61 and the hanging protrusion accommodating parts 55 to accommodate the hanging protrusions 65 and to support the hanging protrusions 65 in a hanging state when the hanging part 61 is in the coupling position. A rotational shaft accommodating part 57 can be provided at a central portion of the engaging part 51 to accommodate a portion of the rotational shaft 67 and to allow the rotational shaft 67 to rotate when the rotational shaft 67 is accommodated therein.

A plurality of the circular arc-shaped accommodating parts 53 are formed in the engaging part 51 such that each circular arc-shaped part 63 is accommodated in the corresponding circular arc shaped accommodating part 53 and can be rotated with the rotational shaft 67. As illustrated in FIGS. 3 and 5, four of the circular arc shaped accommodating parts 53 are formed such that the four circular arc-shaped parts 63 disposed on each rotational shaft 67 at regular intervals can be accommodated in the four circular arc shaped accommodating parts 53, respectively.

The hanging protrusion accommodating parts 55 are larger than the circular arc shaped accommodating parts 53 so that each hanging protrusion 65 formed at one of the circular arc-shaped parts 63 is rotated with the rotational shaft 67 and accommodated in the hanging protrusion accommodating part 55. Thus, the combining supporter 41 can be coupled with the main body 10 by accommodating each hanging protrusion 65 in the corresponding hanging protrusion accommodating part 55 to support each hanging protrusion 65 in the hanging state.

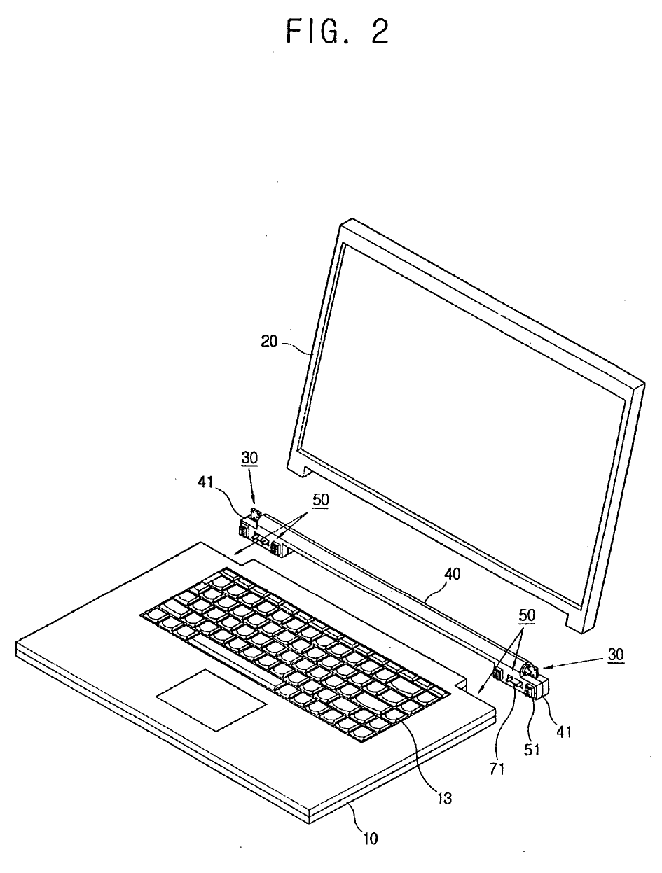

The connecter 71 of the monitor 20 is provided to supply electric power and the image signal to the monitor 20. In a case in which the monitor 20 has a built-in antenna (not shown), the connector 71 can transmit an antenna signal to the main body 10. As illustrated in FIGS. 2, 3, and 5, the connecter 71 is provided on each of the combining supporters 41. However, the present general inventive concept is not limited thereto. For example, the connector 71 can be provided on only one of the combining supporters 41.

The connecting port 73 of the main body 10 is coupled with a connecting port supporting member 74 provided at the rear surface of the main body 10 so that the connector 71 can be connected with the connecting port 73 when the combining member 40 is coupled with the main body 10. A spring member 77 can be provided between the connecting port 73 and the connecting port supporting member 74 to elastically couple the connecting port 73 and the connecting port supporting member 74. The connecting port 73 can also be coupled with the connecting port supporter 74 through a screw 75.

As illustrated in FIG. 5, the spring member 77 can be a coil spring which is coiled around the screw 75. Accordingly, the spring member 77 can absorb a shock generated when the connector 71 is connected with the connecting port 73, and the spring member 77 allows the connecting port 73 to elastically move when the combining member 40 is moved with respect to the main body 10 to prevent the connection between the connector 71 and the connecting port 73 from being broken.

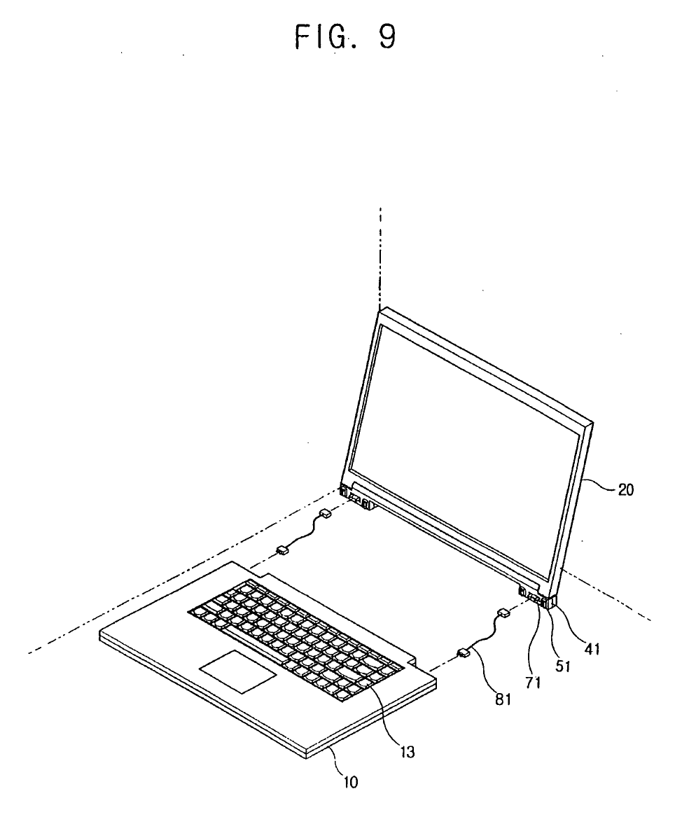

FIG. 9 is a perspective view illustrating the portable computer 1 in a state in which the monitor 20 is detached from the main body 10. As illustrated in FIG. 9, the portable computer 1 can further comprise a connecting cable 81 which connects the connecter 71 and the connecting port 73 when the monitor 20 is separated from the main body 10.

A first end of the connecting cable 81 can be connected to the connector 71 provided at the combining member 40, and a second end of the connecting cable 81 can be connected to the connecting port 73 provided at the main body 10. Accordingly, when the monitor 20 is detached from the main body 10, the monitor 20 can be connected to the main body 10 through the connecting cable 81, and placed at various positions, such as a wall. However, the connecting cable 81 can be provided such that the first end of the connecting cable 81 is connected to the connector 71 provided at the combining member 40 and the second end is connected to a connecting port provided at a separate computer system (not shown) other than the main body 10. Accordingly, the monitor 20 can be connected to other computer systems (not shown) in addition to the main body 10.

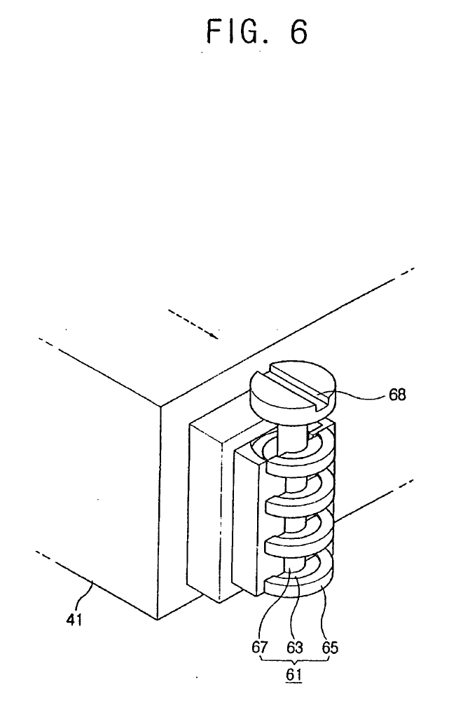

FIGS. 6-8 illustrate operations of the locking unit 50 of the portable computer 1. Referring to FIGS. 1-9, operations of the portable computer 1 will be described below.

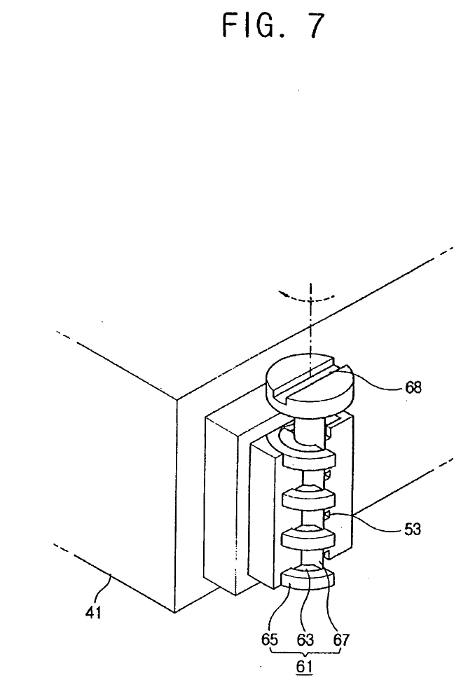

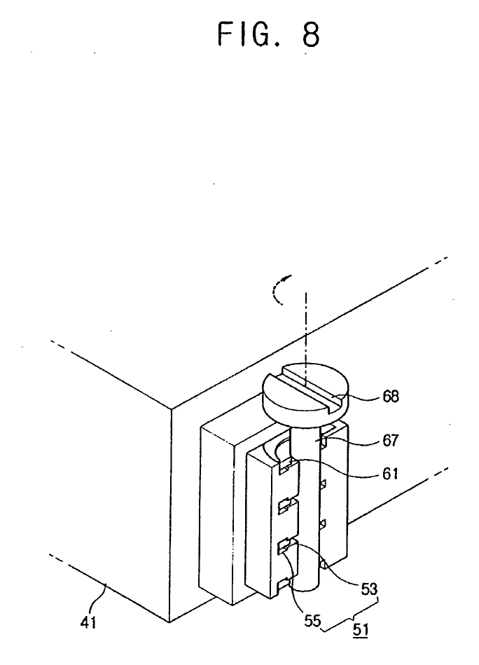

When the combining member 40 is detached from the main body 10, the engaging part 51 of the combining member 40 can be moved toward the hanging part 61 of the main body 10. As illustrated in FIG. 6, the hanging part 61 is rotated to the separation position in which the rotational shaft 67 is accommodated by the rotational shaft accommodating part 57, but the circular arc shaped parts 63 and the hanging protrusions 65 are not accommodated by the circular arc shaped accommodating parts 53 and hanging protrusion accommodating parts 55, respectively. When the rotational shaft accommodating part 57 of the engaging part 51 accommodates the rotational shaft 67, the connector 71 can be connected with the connecting port 73. Then, as illustrated in FIGS. 7 and 8, the rotational shaft 67 can be rotated to the coupling position by rotating a coin or a screwdriver accommodated in the tool accommodating part 68 of the rotational shaft 67. Thus, the hanging part 61 rotates integrally with the rotational shaft 67 and is hung on the engaging part 51. That is, the circular arc-shaped parts 63 and hanging protrusions 65 of the hanging part 61 are rotated integrally with the rotational shaft 67, and accommodated in the corresponding circular arc shaped accommodating parts 53 and the corresponding hanging protrusion accommodating parts 55 of the engaging part 51, respectively, to be supported in the hanging state. Accordingly, the combining member 40 and the main body 10 can be easily coupled with each other to attach the monitor 20 to the main body 10.

In order to separate the combining member 40 from the main body 10, the rotational shaft 67 can be rotated to the separating position by rotating the coin or the screwdriver accommodated in the tool accommodating part 68 of the rotational shaft 67. The hanging part 61 rotates integrally with the rotational shaft 67, and the hanging part 61 is separated from the engaging part 51 by the rotation of the hanging part 61. That is, when the rotational shaft 67 rotates to the separating position, the circular arc shaped parts 63 and the hanging protrusions 65 rotate with the rotational shaft 67 and are not accommodated by the circular arc shaped accommodating parts 53 and hanging protrusion accommodating parts 55, respectively, and are no longer in the hanging state. The combining member 40 can then be detached from the main body 10 to detach the monitor 20 from the main body 10. When the combining member 40 is detached from the main body 10, the engaging part 51 of the combining member 40 can be separated from the rotational shaft 67 at the same time that the connector 71 is disconnected from the connecting port 73. Accordingly, the combining member 40 and the main body 10 can be easily separated from each other.

As described above, in the portable computer 1 according to the present general inventive concept, the monitor 20 and the main body 10 can be easily coupled with each other and separated from each other by rotating the rotational shaft 67 combined integrally with the hanging part 61.

As described above, a plurality of the hanging parts 61 can be provided at the main body 10, a plurality of the circular arc-shaped parts 63 and the hanging protrusions 65 can be provided at each hanging part 61, a plurality of the engaging parts 51 can be provided at the combining member 40, and a plurality of the circular arc shaped accommodating parts 53 and the hanging protrusion accommodating parts 55 can be provided at each engaging part 51. Accordingly, a coupling force can be increased and vibrations which can be generated when the monitor 20 and the main body 10 are coupled with each other can be minimized by the increased coupling force.

Damage to the connecting port 73 and the connector 71 can be prevented by mounting the spring member 77 to the connecting port 73. As illustrated in FIG. 7, the monitor 20 can be placed at various positions, such as the wall, when detached from the main body 10 and connected to the main body 10 or the like through the connecting cable 81b. Accordingly, the monitor 20 can be used as a display device separate from the main body 10.

In the portable computer 1 as described above, if the monitor 20 is defective, the user can easily detach the defective monitor 20 from the main body 10 and replace the defective monitor 20 with a new monitor.

As described above, according to the present general inventive concept, it is possible to provide a portable computer in which a monitor can be easily mounted to and detached from a main body.

Furthermore, as described above, a monitor can be detached from a main body of a portable computer and the detached monitor can be used as a display device for a computer other than the main body, and vibrations generated when the monitor and the main body are coupled with each other can be minimized.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A portable computer, comprising:
a main body;
a monitor to form an image thereon;
a combining member rotatably coupled with the monitor; and
a locking unit having an engaging part provided at one of the combining member and the main body and a hanging part provided at the other one of the combining member and the main body, the hanging part being capable of attaching and detaching the monitor and the main body by rotating between a coupling position at which the hanging part is coupled with the engaging part and a separating position at which the hanging part is separated from with the engaging part.

2. The portable computer according to claim 1, wherein the locking unit comprises a rotational shaft to rotatably support the hanging part.

3. The portable computer according to claim 2, wherein the hanging part comprises a circular arc-shaped part protruding at a predetermined angle from the rotational shaft in a radial direction of the rotational shaft and a hanging protrusion provided at the circular arc-shaped part to hang on the engaging part when the hanging part is in the coupling position.

4. The portable computer according to claim 3, wherein the engaging part comprises a circular arc shaped accommodating part to accommodate the circular arc-shaped part and a hanging protrusion accommodating part to accommodate the hanging protrusion to support the hanging protrusion in a hanging state when the hanging part is in the coupling position.

5. The portable computer according to claim 2, wherein the engaging part is provided at the combining member, and the hanging part is rotatably provided at the main body.

6. The portable computer according to claim 5, wherein the locking unit further comprises a rotational shaft supporting part provided at the main body to rotatably support the rotational shaft.

7. The portable computer according to claim 6, wherein the combining member comprises a pair of combining supporters spaced a predetermined distance from each other, and the engaging part comprises first and second engaging parts respectively provided at the pair of combining supporters.

8. The portable computer according to claim 7, wherein at least one of the combining supporters comprises a connector, and the main body is provided with a connecting port to be connectable to the connector.

9. The portable computer according to claim 8, further comprising an elastic member provided between the connecting port and the main body to elastically couple the connecting port with the main body.

10. The portable computer according to claim 8, further comprising a connecting cable to connect the connector and the connecting port when the monitor is detached from the main body.

11. The portable computer according to claim 2, wherein the rotational shaft comprises a tool accommodating part formed at one end thereof to accommodate a rotational tool to rotate the rotational shaft.

12. A portable computer, comprising:
a display unit comprising one or more accommodating portions, each accommodating portion having one or more arc shaped grooves; and
a main body comprising one or more rotatable shafts corresponding to the one or more accommodating portions, each rotatable shaft having one or more arc shaped protruding portions protruding therefrom to be accommodated within the one or more arc shaped grooves of the corresponding accommodating portion to attach the display unit to the main body when the respective rotatable shaft rotates to a first position, and to separate from the one or more arc shaped grooves of the corresponding accommodating portion to detach the display unit from the main body when the respective rotatable shaft rotates to a second position.

13. The portable computer according to claim 12, wherein each rotatable shaft comprises a tool accommodating part to accommodate a predetermined rotating tool to rotate the rotatable shaft.

14. The portable computer according to claim 12, wherein the display unit comprises a connector connectable with at least one of the main body and an external device when the display unit is detached from the main body.

15. The portable computer according to claim 15, wherein the main body comprises a connecting port to automatically connect with the connector of the display unit when the display unit is attached to the main body.

16. A portable computer, comprising:
a main body comprising a rotatable hanging unit and a connecting port;
a display unit comprising an engaging unit to couple with the rotatable hanging unit to attach the display unit to the main body and to separate from the rotatable hanging unit in order to detach the display unit from the main body according to a rotation of the rotatable hanging unit, and a connector to automatically connect with the connecting port when the display unit is attached to the main body and connectable to the connecting port of the main body and one or more external devices when the display unit is detached from the main body.

17. The portable computer according to claim 16, wherein the main body further comprises an elastic member to elastically couple the connecting port to the main body and to absorb force generated when the connector of the display unit is automatically connected with the connecting port.

18. The portable computer according to claim 16, wherein the rotatable hanging unit comprises a shaft rotatably supported at the main body and one or more arc shaped protrusions protruding from the shaft, and the engaging unit comprises one or more arc shaped accommodating portions to accommodate the one or more arc shaped protrusions therein to support the one or more arc shaped protrusions in a hanging position when the shaft is rotated to a position in which the one or more arc shaped protrusions are aligned with the one or more arc shape accommodating portions.

19. A display device attachable to a main body of a portable computer, comprising:
a display unit to display an image thereon; and
a coupling unit coupled to the display unit and including an engaging part to engage and disengage with a rotatable portion of the main body of the portable computer according to a rotation of the rotatable portion, and a connector connectable to the main body of the portable computer and to one or more external devices to input the image to be displayed on the display unit.

20. The display device according to claim 19, wherein the connector automatically connects to the main body of the portable computer when the engaging part engages with the rotatable portion of the main body of the portable computer.

21. The display device according to claim 19, wherein the display unit is tiltable with respect to the coupling unit such that when the engaging part of the coupling unit engages with the rotatable portion of the main body of the portable computer, the display unit is tiltable with respect to the main body of the portable computer.
